(19) United States
(12) Patent Application Publication
(10) Pub. No.: US 2020/0028342 A1
(43) Pub. Date: Jan. 23, 2020

(54) LOW VOLTAGE DC ELECTRICAL OUTLETS

(71) Applicants: Norman R. Byrne, Ada, MI (US); Daniel P. Byrne, Lowell, MI (US); Aaron G. Lautenbach, Rockford, MI (US)

(72) Inventors: Norman R. Byrne, Ada, MI (US); Daniel P. Byrne, Lowell, MI (US); Aaron G. Lautenbach, Rockford, MI (US)

(21) Appl. No.: 16/465,859

(22) PCT Filed: Nov. 30, 2017
(86) PCT No.: PCT/IB2017/057552

§ 371 Date: May 31, 2019

Related U.S. Application Data
(60) Provisional application No. 62/429,422, filed on Dec. 2, 2016.

(51) Int. Cl. H02G 3/18; H02G 3/10; H02G 3/16; H02G 3/08; H05K 7/14; H02G 3/12

(52) U.S. Cl. CPC H02G 3/18; H02G 3/10; H02G 3/12; H02G 3/083; H05K 7/1485; H02G 3/16

(57) ABSTRACT

A low voltage power outlet assembly is adapted for providing access to low voltage power in compact spaces. The low voltage power outlet assembly includes a circuit subassembly that is operable to transform a line voltage input, such as about 110V to 220V AC, to a lower voltage output, such as about 2V to 12V DC. Electrical input conductors receive and convey the line voltage from a power source to the circuit subassembly, while electrical conductors convey the lower voltage output from the circuit subassembly to a low voltage power receptacle that is arranged in a same housing as the circuit subassembly. The low voltage power outlet is mountable in different housings, faceplates, and the like, to accommodate different mounting styles and locations. The low voltage power receptacle includes at least two different receptacles, such as a USB Type-A outlet and a USB Type-C outlet.

### FIELD OF THE INVENTION

The present invention relates to low voltage electrical power outlets or receptacles, with or without electronic data capability, for use in work areas or the like.

### BACKGROUND OF THE INVENTION

Low voltage power and data outlets, such as USB and USB Power outlets, are in increasing demand as the number of electrical and electronic devices that use such outlets continues to increase. Such devices may include, for example, mobile phones, computers and computing devices, digital cameras, communications equipment, and the like. Therefore, there has been increasing demand for access to such outlets in work areas, homes, and even public spaces such as airports, shopping malls, personal and public transit vehicles, and the like.

### SUMMARY OF THE INVENTION

The present invention provides a low voltage power outlet assembly that is adapted to provide access to low voltage power in compact spaces. The low voltage power outlet assembly includes a circuit subassembly with a power transformer for reducing a line voltage (e.g., 110V AC or 220V AC), such as may be received from standard receptacle outlets, down to a lower voltage (such as about 5V DC, for example), which is made available to a user at a low voltage power outlet, such as a USB-style power outlet. The low voltage power outlet assembly's circuit subassembly, which may be included in a housing with the receptacles, converts or transforms standard line voltage to a lower voltage power output for use by low voltage power consumers such as phones, computers, cameras, hand-held electronic devices, and the like.

According to one embodiment of the present invention, a low voltage power outlet assembly includes a circuit subassembly, electrical input conductors, electrical output conductors, and a low voltage power outlet which are all arranged in a housing that is mounted in a user-accessible location. The circuit subassembly is operable to transform a line voltage input to a lower voltage output. The electrical input conductors are coupled to the circuit subassembly and are configured to receive and convey the line voltage from a power source to the circuit subassembly. The electrical output conductors are coupled to the low voltage power receptacle and to the circuit subassembly, and convey the lower voltage output from the circuit subassembly to the low voltage power outlet.

In one aspect, the outlet assembly further includes a housing that receives and supports the low voltage power outlet in the user-accessible location. Optionally, the outlet housing may be configured to slidably engage an elongate channel member of a power and/or data assembly.

In another aspect, the outlet housing is configured for mounting along a work surface.

In yet another aspect, the outlet housing is in combination with or incorporated into a power or data center such as a pop-up worksurface-mounted center, an edge-mounted center, a hole-mounted center, or a center with lighting.

In a further aspect, the low voltage power outlet is one or more USB-style outlets.

In a still further aspect, the one or more USB-style receptacles may be USB Type-A outlets and/or USB Type-C outlets. Optionally a single USB Type-A outlet and a single USB Type-C outlet are arranged in a single housing. Optionally a pair of USB Type-C outlets are arranged in a single housing.

In another aspect, the USB-style outlets are supplied with 5V DC from a single power transformer, via a controller that downconverts the power transformer's 20V DC outlet to 5V DC at 2 Amperes.

In yet another aspect, the housing includes a faceplate with a variety of openings, each of the openings sized for a particular one of a plurality of different sized low voltage receptacles.

Therefore, the low voltage power outlet assembly provides users with convenient access to low voltage charging ports, which may include two or more charging ports having different configurations in the same housing, such as in work or study areas, or in transit vehicles or stations, or substantially anywhere that such access to low voltage power is desired. The low voltage power outlet assembly may optionally be incorporated into existing power or data centers.

These and other objects, advantages, purposes and features of the present invention will become apparent upon review of the following specification in conjunction with the drawings.

### BRIEF DESCRIPTION OF THE DRAWING

FIG. 1 is an exemplary block diagram of a low voltage power outlet assembly in accordance with an embodiment of the present invention;

FIGS. 2A and 2B are exemplary faceplate views of an outlet housing for USB-style outlets, in accordance with an embodiment of the present invention;

FIGS. 3A and 3B are exemplary block diagrams of a low voltage power outlet assembly, in accordance with an embodiment of the present invention; and

FIG. 4 is a partially-exploded perspective view of a power and/or data center including the low voltage power receptacle assembly of FIG. 1 in a self-contained unit, including an enlarged view of the self-contained unit with portions cut away for clarity.

### DESCRIPTION OF THE PREFERRED EMBODIMENTS

An exemplary low voltage power outlet assembly is presented that preferably includes a pair of USB-style outlets that are mounted in a same housing as a circuit subassembly. As discussed herein, the low voltage power outlet assembly may include a pair of USB Type-C outlets or a pair of USB-style outlets that include a USB Type-A outlet and a USB Type-C outlet. As also discussed herein, the pair of USB-style outlets will be provided with 5V DC by a controller that is coupled to a single power transformer that converts the supplied line voltage (110V AC or 220V AC) to a fixed 20V DC that is down-converted to the desired 5V DC by the controller.

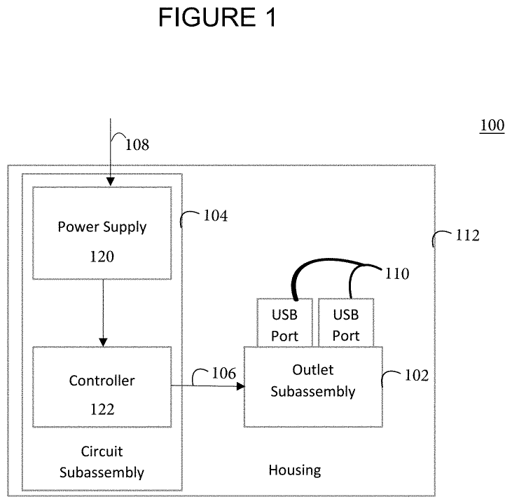

Referring now to the drawings and the illustrative embodiments depicted therein, a low voltage power outlet assembly 100 includes an outlet subassembly 102 that is electrically coupled to a circuit subassembly 104 via electrical output conductors 106, which may typically be made up of two or more flexible wires, a ribbon cable, or the like (FIG. 1). Using various faceplates, housings, mounting surfaces, and the like, as will be described in more detail herein, the low voltage power outlet assembly 100 may be adapted for installation in various arrangements and locations such as, for example, a power and/or data center utilizing an elongate channel member. Such arrangements are described in detail in commonly owned U.S. Pat. No. 9,312,673 (the '673 patent), which is hereby incorporated herein by reference in its entirety.

Circuit subassembly 104 converts or transforms a line voltage input received from electrical input conductors 108 (FIG. 1) to a lower voltage output that is supplied to the outlet subassembly 102 by the electrical output conductors 106. In one embodiment, the outlet subassembly 102 may be coupled directly to the circuit subassembly 104 such that electrical output conductors 106 are not required, as the outlet subassembly 102 would be coupled directly to outputs of the circuit subassembly 104.

As illustrated in the embodiment of FIG. 1, the circuit subassembly 104 comprises a power supply 120 and a controller 122. In this embodiment, the power supply 120 is operable to convert the line voltage to a constant 20V DC, while the controller 122 is operable to downconvert the 20V DC to 5V DC at 2 amperes (A) for the outlet subassembly 102. In another embodiment, the power supply 120 and controller 122 of the circuit subassembly 104 are an integral unit.

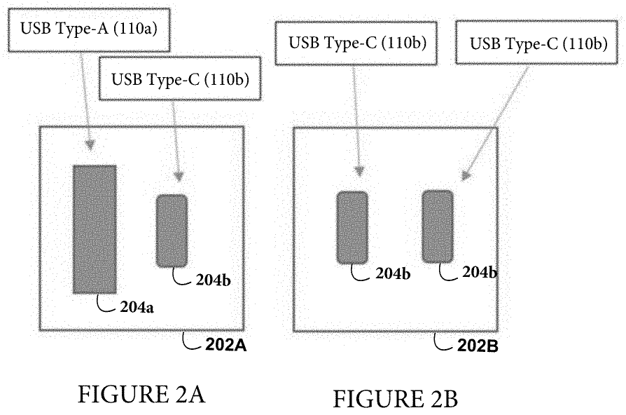

As illustrated in FIG. 1, the outlet subassembly 102 includes two low voltage electrical outlets 110 which, in the illustrated embodiment, are configured as USB-Style charging or power ports, with each USB-style charging or power port receiving 5V DC at 2 A. In a further embodiment, the USB-style charging or power ports 110a, 110b may be configured such that one of them (110a) is a Type-A USB charging or power port, while the other (110b) is a Type-C USB charging or power port (FIG. 2A). In yet a further embodiment, also illustrated in FIG. 2B, the USB-style charging or power ports 110 may be configured such that both of them are Type-C USB charging or power ports 110b. In one embodiment, the outlet subassembly 102 is without data capability. However it will be appreciated that substantially any type or configuration of port or outlet may be used, without departing from the spirit and scope of the present invention. For example, the charging or power ports may further provide data and/or voice transmission capability via digital or analog signals transmitted through additional conductors and terminals that are provided for that purpose.

It will further be appreciated that the outlet subassembly 102 may have as few as one low voltage electrical outlet 110, or may have three or more of such outlets, including two or more different styles of electrical receptacle at a single outlet assembly (FIG. 1). Low voltage electrical outlets 110a, 110b are mounted in openings 204a, 204b of a faceplate 202A or 202B (FIGS. 2A and 2B, respectively), of a housing 112 that is generally a boxy enclosure, and may be shaped as a six-sided body such as a cuboid or cube, or a parallelepiped. The faceplate 202A, 202B may be unitarily formed from resinous plastic such that a single piece of resinous plastic with an appropriate number of openings 204a and/or 204b may be utilized. Additional embodiments and details for the housing 112 may be found below, and also in the above mentioned '673 patent.

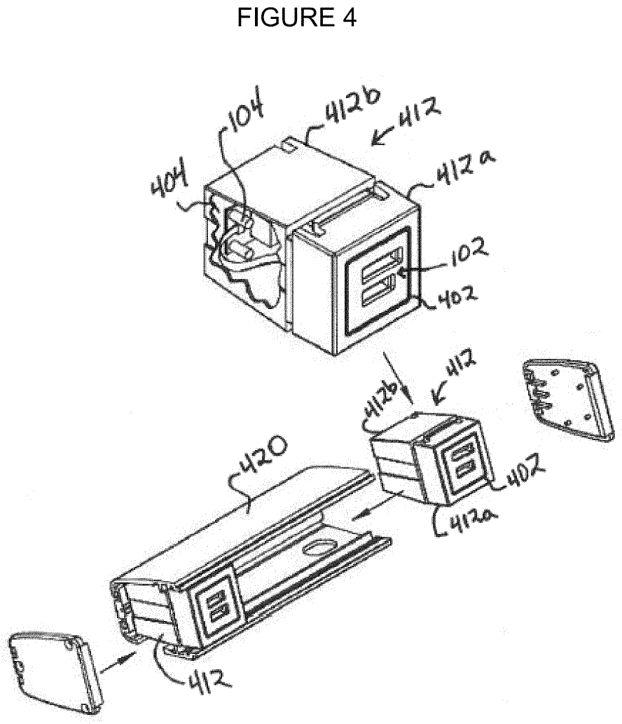

FIG. 4 illustrates an exemplary embodiment wherein the housing 112 illustrated in FIG. 1 is an enclosed receptacle housing 412 that includes a front housing portion 412a in which a faceplate 402 and an outlet subassembly 102 can be mounted, and a rear housing portion 412b that defines a substantially enclosed space 404 in which a circuit subassembly 104 can be mounted. The circuit subassembly 104 and the outlet subassembly 102 can therefore be assembled together in the receptacle housing 412 to form a substantially self-contained low voltage power unit that can be slidably engaged with the elongated channel members 420 illustrated in FIG. 4, and also as further discussed in the above mentioned '673 patent. As also illustrated in FIG. 4, a plurality of the receptacle housings 412 may be slidably engaged with the elongated channel members 420.

As illustrated in FIGS. 2A and 2B, the faceplates 202A, 202B each have a generally square front defining two generally rectangular openings 204a, 204b that are sized and aligned to provide access to the electrical outlets 110a, 110b when the circuit subassembly 104 and the outlet subassembly 102 are received in the housing 112. As also illustrated in FIGS. 2A and 2B and discussed herein, the openings 204a, 204b in the faceplate 202a, 202b may be sized depending upon the type of USB port. For example, the openings 204b may be a size and/or configuration to accommodate USB type-C outlets 110b, or the openings 204a may be a size and/or configuration to accommodate USB type-A outlets 110a (see FIG. 2A). Or the openings 204a, 204b may be of a variety of dimensions to accommodate a USB type-A outlet 110a and a USB type-C outlet 110b (see FIG. 2B). Thus, the openings 204a, 204b and corresponding outlets 110a, 110b may be configured to receive different plugs associated with the same or different types of electronic or electrical devices, so that a plug that is compatible with the first opening 204a and outlet 110a is incompatible with the second opening 204b and/or second outlet 110b, and likewise a plug that is compatible with the second opening 204b and outlet 110b is incompatible with the first opening 204a and/or second outlet 110a.

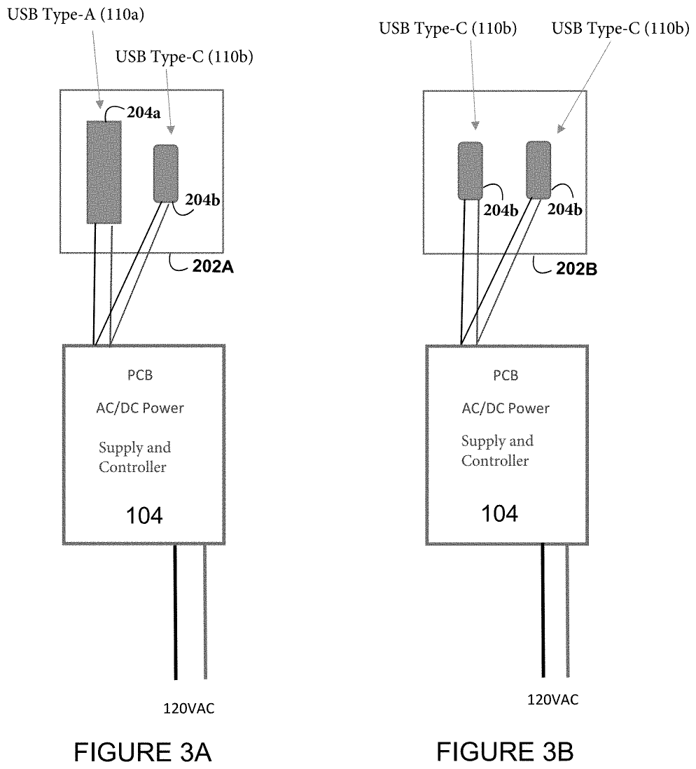

As illustrated in FIGS. 3A and 3B, the circuit subassembly 104 may be configured as a printed circuit board (PCB) based AC/DC power supply with controller operable to convert the line voltage from 110V AC or 220V AC to 20V DC (or similar direct current voltage level), and then down-convert the supplied DC voltage to the desired 5V DC at 2 A for delivery to the electrical outlets 110a, 110b. In other respects, the faceplates 202A, 202B of FIGS. 3A and 3B may be substantially similar to the faceplates 202A, 202B of FIGS. 2A and 2B, including generally square one-piece faceplates 202A, 202B with respective openings 204a, 204b sized to fit USB Type-A outlets 110a and USB Type-C outlets 110b, respectively.

Thus, the low voltage power outlet assembly provides users with convenient access to low voltage charging ports, which may include two or more charging ports having different configurations (e.g., USB Type-A and USB Type-C) in the same housing, such as in work or study areas, or in transit vehicles or stations, or substantially anywhere that such access to low voltage power is desired. Optionally, the multiple charging ports in a single housing may be provided with the same or different electrical voltage and/or amperage.

Changes and modifications in the specifically-described embodiments may be carried out without departing from the principles of the present invention, which is intended to be limited only by the scope of the appended claims as interpreted according to the principles of patent law including the doctrine of equivalents.

1. A low voltage DC power outlet assembly comprises:
a circuit subassembly comprising a power supply and a controller;
electrical input conductors and electrical output conductors; and
a low voltage power outlet arranged in a housing that is configured to be mounted in a user-accessible location, wherein the low voltage power outlet comprises at least two electrical receptacles, and wherein the at least two electrical receptacles comprise different physical dimensions, and wherein a plug compatible with a first of the at least two electrical receptacles is incompatible with a second of the at least two electrical receptacles;
wherein the power supply is operable to transform a line voltage input via the electrical input conductors to a lower voltage output;
wherein the electrical input conductors are coupled to the power supply and are configured to receive and convey the line voltage from a power source to the power supply; and
wherein the electrical output conductors are coupled to the controller of the circuit subassembly and to the low voltage power outlet, and convey the lower voltage output from the power supply, via the controller, to both of the at least two electrical receptacles of the low voltage power outlet.

2. The low voltage power outlet assembly of claim 1, wherein the at least two electrical receptacles of the low voltage power outlet comprise two or more different USB-style outlets.

3. The low voltage power outlet assembly of claim 1, wherein the at least two electrical receptacles of the low voltage power outlet comprise at least one USB Type-A outlet and at least one USB Type-C outlet.

4. The low voltage power outlet assembly of claim 1, further in combination with a power or data center comprising one of a pop-up worksurface-mounted center, an edge-mounted center, a hole-mounted center, and a center with lighting.

5. The low voltage power outlet assembly of claim 1, wherein the housing is configured to slidably engage an elongate channel member of a power and/or data assembly.

6. The low voltage power outlet assembly of claim 1, wherein the housing is configured for mounting along a work surface.

7. The low voltage power outlet assembly of claim 1, wherein the housing comprises a faceplate configured for providing access to the at least two electrical receptacles of the low voltage power outlet.

8. The low voltage power outlet assembly of claim 7, wherein the faceplate comprises a plurality of spaced-apart openings, each opening having different dimensions for providing access to a respective one of the at least two receptacles.

9. The low voltage power outlet assembly of claim 7, wherein the faceplate is square-shaped.

10. The low voltage power outlet assembly of claim 7, wherein the faceplate is unitarily formed.

11. The low voltage power outlet assembly of claim 7, wherein the faceplate is formed of resinous plastic.

12. The low voltage power outlet assembly of claim 1, wherein the controller is configured to downconvert the lower voltage output from the power supply.

13. The low voltage power outlet assembly of claim 12, wherein the controller is configured to supply 5V DC at 2 amperes to both of the at least two electrical receptacles of the low voltage power outlet.

14. The low voltage power outlet assembly of claim 12, wherein the power supply is configured to reduce the line voltage to a low DC voltage, and wherein the low DC voltage is the lower voltage output.

15. A low voltage DC power outlet assembly comprising:
a circuit subassembly comprising a power supply and a controller;
electrical input conductors and electrical output conductors, wherein the electrical input conductors are coupled to the power supply and are configured to receive and convey line voltage from a power source to the power supply, and wherein the power supply is configured to transform the line voltage input via the electrical input conductors to a low voltage DC output of about 20V DC;
a low voltage power outlet comprising at least two electrical receptacles having different physical dimensions, wherein the at least two electrical receptacles comprise at least one USB Type-A outlet and at least one USB Type-C outlet; and
a housing configured to be mounted in a user-accessible location, wherein the housing is configured to slidably engage an elongate channel member of a power and/or data assembly, and wherein the circuit subassembly and the low voltage power outlet are arranged in the housing;
wherein the housing is a unitarily formed box-shaped enclosure, and comprises a faceplate formed of resinous plastic, which faceplate is configured for providing access to the at least two electrical receptacles of the low voltage power outlet, wherein the faceplate comprises a plurality of spaced-apart openings, each opening having different dimensions for providing access to a respective one of the at least two receptacles; and
wherein the electrical output conductors are coupled to the controller of the circuit subassembly and to the low voltage power outlet, and convey the low voltage output from the power supply, via the controller, to both of the at least two electrical receptacles of the low voltage power outlet, and wherein the controller is configured to downconvert the low voltage output of about 20V DC to supply about 5V DC at about 2 amperes to both of the at least two electrical receptacles of the low voltage power outlet.
